(19) United States
(12) Patent Application Publication
(10) Pub. No.: US 2025/0338716 A1
(43) Pub. Date: Oct. 30, 2025

(54) ARRAY SUBSTRATE, DISPLAY PANEL AND DISPLAY DEVICE

(71) Applicant: Hubei Yangtze Industrial Innovation Center of Advanced Display Co., Ltd., Wuhan (CN)

(72) Inventor: Weiwei Yang, Wuhan (CN)

(73) Assignee: Hubei Yangtze Industrial Innovation Center of Advanced Display Co., Ltd., Wuhan (CN)

(21) Appl. No.: 18/777,600

(22) Filed: Jul. 19, 2024

(30) Foreign Application Priority Data
Apr. 30, 2024 (CN) 202410547345.2

(51) Int. Cl. H10K 59/121; H01L 27/12

(52) U.S. Cl. CPC H10K 59/1213; H10D 86/421; H10D 86/60

(57) ABSTRACT

An array substrate, a display panel and a display device are provided by the present application. The array substrate includes a substrate and a thin film transistor. The thin film transistor is located on a side of the substrate, the thin film transistor includes an active layer, a gate, and a source-drain electrode, the active layer includes at least one first active portion and at least one second active portion, which are arranged in different layers, a projection of the first active portion at least partially does not overlap a projection of the second active portion, the source-drain electrode is located on a side of the active layer away from the substrate, and the first active portion and the second active portion are connected to the source-drain electrode. The first active portion and the second active portion includes an oxide semiconductor.

### CROSS REFERENCES TO RELATED APPLICATIONS

This application claims a priority of Chinese Patent Application No. 202410547345.2, filed on Apr. 30, 2024 and titled by “ARRAY SUBSTRATE, DISPLAY PANEL AND DISPLAY DEVICE”, which is incorporated herein in its entirety.

### TECHNICAL FIELD

The present application relates to the technical field of display, and in particular to an array substrate, a display panel and a display device.

### BACKGROUND

With the development of science and technology, the field of a display panel has been rapidly developed. The demand for the display panel is further increasing. Thus, how to further improve the display effect of the display panel has become the main research direction to the manufacturers.

### SUMMARY

Embodiments of the present application provide an array substrate, a display panel and a display device, which can improve the display effect.

In the first aspect, the embodiments of the present application provide an array substrate including a substrate and a thin film transistor. The thin film transistor is located on a side of the substrate, the thin film transistor includes an active layer, a gate, and a source-drain electrode, the active layer includes at least one first active portion and at least one second active portion, the first active portion and the second active portion are arranged in different layers, a projection of the first active portion in a direction perpendicular to the substrate and a projection of the second active portion in the direction perpendicular to the substrate are at least partially non-overlapping, the source-drain electrode is located on a side of the active layer away from the substrate, and the first active portion and the second active portion being connected to the source-drain electrode. A non-overlapping region between the first active portion and the second active portion at least partially overlaps the gate in the direction perpendicular to the substrate. The first active portion and the second active portion include an oxide semiconductor. The present application can improve the display effect.

In a second aspect, the embodiments of the present application provide a display panel including the array substrate as described above.

In a third aspect, the embodiments of the present application provide a display device including the display panel as described above.

### BRIEF DESCRIPTION OF THE DRAWINGS

The features, the advantages, and the technical effects in the exemplary embodiments of the present application will be described below with reference to the drawings.

FIG. 1 shows a top structural schematic view of an array substrate according to some embodiments of the present application;

FIG. 2 shows a cross-sectional structural schematic view on line A-A in FIG. 1;

FIG. 3 shows a cross-sectional structural schematic view on line B-B in FIG. 1;

FIG. 4 shows a cross-sectional structural schematic view of an array substrate according to some embodiments of the present application;

FIG. 5 shows a top structural schematic view of a first active portion of an array substrate according to some embodiments of the present application;

FIG. 6 shows a cross-sectional structural schematic view of another array substrate according to some embodiments of the present application;

FIG. 7 shows a cross-sectional structural schematic view of another array substrate according to some embodiments of the present application;

FIG. 8 shows a cross-sectional structural schematic view of another array substrate according to some embodiments of the present application;

FIG. 9 shows a cross-sectional structural schematic view of another array substrate according to some embodiments of the present application;

FIG. 10 shows a cross-sectional structural schematic view of another array substrate according to some embodiments of the present application;

FIG. 11 shows a cross-sectional structural schematic view of another array substrate according to some embodiments of the present application;

FIG. 12 shows a cross-sectional structural schematic view of a display panel according to some embodiments of the present application;

FIG. 13 shows a structural schematic view of a driving circuit of a display panel according to some embodiments of the present application;

FIG. 14 shows a structural schematic view of a control circuit of a display panel according to some embodiments of the present application; and

FIG. 15 shows a top structural schematic view of a display device according to some embodiments of the present application.

### REFERENCE NUMERALS

100. array substrate; 200. display panel; 300. display device;
10. substrate;
20. thin film transistor; 21. active layer; 211. first active portion; 212. second active portion; 213. third active portion; 214. fourth active portion; 215. connecting line; 22. gate; 221. first gate; 222. second gate; 23. source-drain electrode; 231. source; 232. drain; 24. first thin film transistor; 25. second thin film transistor;
G. active layer effective region; G1. first active layer effective region; G2. second active layer effective region; G3. third active layer effective region; H. avoiding hole;
AA. first region; NA. second region;
Tm. driving transistor; T1. threshold-compensating transistor; T2. data-writing transistor; T3. first light-emitting control transistor; T4. second light-emitting control transistor; T5. reset transistor; T6 bias adjustment transistor; OL. light-emitting unit; PV1. first power signal terminal; PV2. second power signal terminal;
M1. first transistor; M2. second transistor; M3. third transistor; M4. fourth transistor; M5. fifth transistor; M6. sixth transistor; M7. seventh transistor; M8. eighth transistor; OUT. output terminal; CK1. clock signal terminal; VGH. first level signal terminal; VGL. second level signal terminal;
C1. first capacitor; C2. Second capacitor; C3. third capacitor; C4. fourth capacitor;
N1. first node; N2. second node; N3. third node; N4. fourth node; N5. fifth node; N6. sixth node; N7. seventh node;
X. first direction; Y. second direction; Z. direction perpendicular to a substrate.

In the drawings, the same components are marked with the same reference numeral. The drawings are not drawn to the actual scale.

### DETAILED DESCRIPTION

Features and exemplary embodiments in various aspects of the present application will be described in detailed below. To make the objects, technical solutions and advantages of the present disclosure to be more apparent, the present disclosure will be further described in detail below with reference to the accompanying drawings and specific embodiments. It shall be understood that the specific embodiments described herein are only to be construed as illustrative and not limiting. To those skilled in the art, the present application can be implemented without some of the specific details. The description of embodiments below is intended merely to provide a better understanding of the present application by showing examples of the present application.

It shall be noted that, in this context, relational terms such as first and second are merely used to distinguish one entity or operation from another entity or operation, and do not necessarily require or imply any such actual relationship or order between the entities or operations. Further, the term “comprise”, “include” or any other variations thereof is intended to encompass a non-exclusive inclusion, such that a process, method, article, or device including a plurality of elements includes not only these elements but also other elements not listed, or elements that are inherent to such process, method, article or device. Without more limitations, an element that is defined by an expression “comprises . . . ”, does not exclude other identical elements in the process, method, article, or device including this element.

In some high load regions of a display device, such as a cell test region, a Gate on Array (GOA) region, and Demux region, in order to drive the high loads, the thin film transistor (TFT) including a channel with a large width-to-length ratio is generally used.

In the existing thin film transistor structure, the thin film transistor includes a gate, active layer, source and drain. Two ends of the active layer are connected to the source and the drain, respectively, and a channel is formed between the source and the drain. However, due to the large area of the active layer, the heat-dissipating efficiency of the active layer decreases, thereby leading to a decrease in the performance of thin-film transistor and reducing the display effect of the display panel.

In view of the above problems, in a first aspect, embodiments of the present application provide an array substrate.

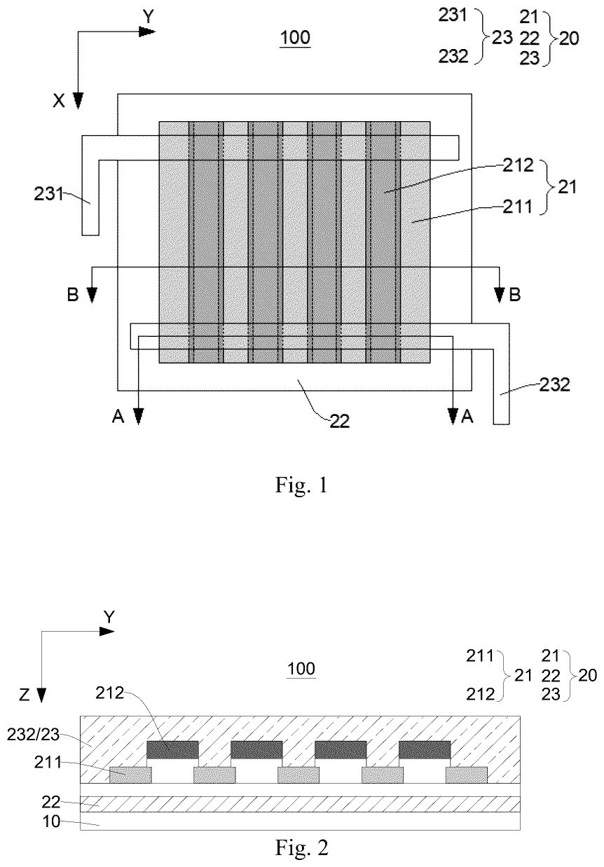

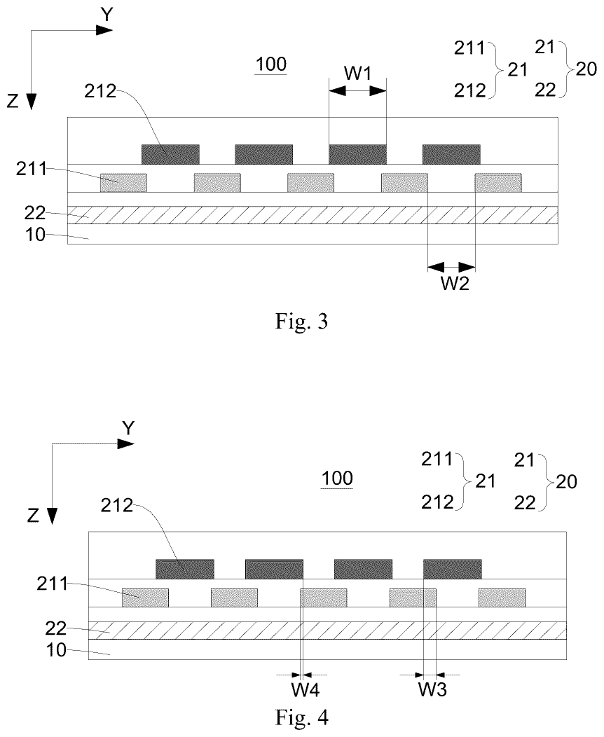

FIG. 1 shows a top structural schematic view of an array substrate according to some embodiments of the present application; FIG. 2 shows a cross-sectional structural schematic view on line A-A in FIG. 1; and FIG. 3 shows a cross-sectional structural schematic view on line B-B in FIG. 1.

As shown in FIG. 1 to FIG. 3, the embodiments of the present application provide an array substrate 100 including a substrate 10 and a thin film transistor 20. The thin film transistor 20 is located on a side of the substrate 10. The thin film transistor 20 includes an active layer 21, a gate 22 and a source-drain electrode 23. The active layer 21 includes at least one first active portion 211 and at least one second active portion 212. The first active portion 211 and the second active portion 212 are arranged in different layers. A projection of the first active portion 211 in a direction Z perpendicular to the substrate and a projection of the second active portion 212 in the direction Z perpendicular to the substrate are at least partially non-overlapping. The source-drain electrode 23 is located on a side of the active layer 21 away from the substrate 10. The first active portion 211 and the second active portion 212 are connected to the source-drain electrode 23. A non-overlapping region between the first active portion 211 and the second active portion 212 at least partially overlaps the gate 22 in the direction Z perpendicular to the substrate. The first active portion 211 and the second active portion 212 includes an oxide semiconductor.

The substrate 10 is mainly used to support and load, and other film layers are sequentially stacked on the substrate 10. The expression “stacked” here means that other film layers are sequentially arranged in a thickness direction of the substrate 10. Herein, the substrate 10 may include a plurality of film layer structures, and specific compositions of the film layer structures of the substrate 10 are not limited in the embodiments of the present application. A thickness direction of other film layers located on a side of substrate 10 and the direction Z perpendicular to the substrate are usually consistent with the thickness direction of substrate 10 itself. Therefore, in order to the convenience of expression, the thickness direction of the substrate 10, the thickness direction of other film layers or the direction Z perpendicular to the substrate mentioned in the embodiments of the present application below are all represented in the same direction.

The thin film transistor 20 is located on the side of the substrate 10, and the gate 22 may be located between the active layer 21 and the substrate 10. Alternatively, the gate 22 may be located on the side of the active layer 21 away from the substrate 10. Optionally, an insulating layer is arranged between the gate 22 and the active layer 21. Optionally, a material of the insulating layer includes an inorganic material, such as silicon oxide or silicon nitride. The source-drain electrode 23 is located on a side of the active layer 21 away from the substrate 10. The source-drain electrode 23 includes a source 231 and a drain 232, which are located at two ends of the active layer 21, respectively, and connected to the active layer 21.

A direction of a length of the active layer 21 in the first direction X may be a length direction of active layer 21, and a direction of a length of the active layer 21 in the second direction Y may be a width direction of the active layer 21. Optionally, the source 231 and the drain 232 are connected to the two ends of the active layer 21 in the first direction X, respectively. The active layer 21 includes a first active portion 211 and a second active portion 212, which are insulated from each other. Optionally, an insulating material between the first active portion 211 and the second active portion 212 includes an inorganic material. In some other examples, the first active portion 211 and the second active portion 212 can be directly in contact with each other.

Optionally, there may be one or more first active portions 211.

Optionally, there may be one or more second active portions 212.

Optionally, the number of the first active portion 211 may be the same as the number of the second active portion 212. Alternatively, the number of the first active portion 211 may be different from the number of the second active portion 212.

Optionally, the first active portion 211 may be located between the second active portion 212 and the substrate 10. Alternatively, the first active portion 211 may be located on a side of the second active portion 212 away from the substrate 10. For example, the first active portion 211 is located between the second active portion 212 and the substrate 10 in the following text.

Optionally, the first active portion 211 may be extended in the first direction X. Optionally, an extending direction of the second active portion 212 is the same as an extending direction of the first active portion 211. Exemplarily, a shape of an orthographic projection of the first active portion 211 on the substrate 10 is in a strip shape, a shape of an orthographic projection of the second active portion 212 on the substrate 10 is in a strip shape, and a shape of an orthographic projection of the active layer 21 formed by the first active portion 211 and the second active portion 212 together on the substrate 10 is in a rectangle shape. Alternatively, in some other examples, the first active portion 211 may extend in another direction, for example, the shape of the orthographic projection of the first active portion 211 on the substrate 10 is in an arc shape.

In some examples, an edge of the projection of the first active portion 211 in the direction Z perpendicular to the substrate is tangent to an edge of the projection of the second active portion 212 in the direction Z perpendicular to the substrate. In some other examples, the edge of the projection of the first active portion 211 in the direction Z perpendicular to the substrate partially overlaps the edge of the projection of the second active portion 212 in the direction Z perpendicular to the substrate. In some other examples, the edge of the projection of the first active portion 211 in the direction Z perpendicular to the substrate is spaced apart from the edge of the projection of the second active portion 212 in the direction Z perpendicular to the substrate.

The first active portion 211 and the second active portion 212 are connected to the source-drain electrode 23, that is, two end of the first active portion 211 in the first direction X are connected to the source 231 and the drain 232, respectively, and two end of the second active portion 212 in the first direction X are connected to the source 231 and the drain 232, respectively. A surface of the second active portion 212 away from the substrate 10 can directly abut against the source-drain electrode 23. The source-drain electrode 23 extends in a direction towards the first active portion 211 to form a protruding structure, which abuts against a surface of the first active portion 211 away from the substrate 10. Optionally, a side wall of the protruding structure can abut against a side wall of the second active portion 212.

In the direction Z perpendicular to the substrate, the non-overlapping region between the first active portion 211 and the second active portion 212 at least partially overlaps with the gate 22, that is, there is the non-overlapping region between the projection of the first active portion 211 in the direction Z perpendicular to the substrate and the projection of the second active portion 212 in the direction Z perpendicular to the substrate, and the non-overlapping region completely overlaps a projection of the gate 22 in the direction Z perpendicular to the substrate. Alternatively, in some examples, the non-overlapping region partially overlaps the projection of the gate 22 in the direction Z perpendicular to the substrate. In some other examples, the non-overlapping region may be located within the projection of gate 22 in the direction Z perpendicular to the substrate. In some other examples, the projection of gate 22 in the direction Z perpendicular to the substrate may be located within the non-overlapping region.

The first active portion 211 and the second active portion 212 include an oxide semiconductor. Optionally, each of the materials of the first active portion 211 and the second active portion 212 includes IGZO (indium gallium zinc oxide).

In the embodiments of the present application, the array substrate 100 includes the thin film transistor 20, which includes the first active portion 211 and the second active portion 212, and each of the first active portion 211 and the second active portion 212 includes the oxide semiconductor. The oxide semiconductor has a high resistivity and generates a large amount of heat during the operation of the thin film transistor 20. The complete active layer can be divided into a plurality of first active portions 211 and a plurality of second active portions 212, which can effectively increase an area of a side face of the active layer 21, increase a heat-dissipating channel of the active layer 21, ensure that the active layer 21 has a sufficient heat-dissipating surface, and improve the overall heat-dissipating performance of the active layer 21. The first active portion 211 and the second active portion 212 are arranged in different layers, which can reduce the space occupied by the first active portion 211 and the second active portion 212 in the thin film transistor 20 while ensure the heat-dissipating performance of the active layer 21. Therefore, the overall area of the active portion can increase as much as possible, the overall size of the thin film transistor 20 can be reduced, the overall performance of the thin film transistor 20 can be improved, and the display effect of the display panel 200 can be improved.

As shown in FIG. 1 to FIG. 3, in some optional embodiments, at least one second active portion 212 is arranged between two adjacent first active portions 211 in a direction parallel to a plane where the substrate 10 is located and perpendicular to an extending direction of the first active portion 211. That is, at least one second active portion 212 is arranged between two adjacent first active portions 211 when viewed in the direction Z perpendicular to the substrate.

Exemplarily, one or more projections of the second active portion 212 in the direction Z perpendicular to the substrate can be arranged between two projections of the two adjacent first active portions 211 in the direction Z perpendicular to the substrate.

In this embodiment of the present application, by the above arrangement, it is beneficial to increasing the number of the first active portions 211 and the second active portions 212 which are arranged, while reducing the size of the active layer 21 in the length direction or the width direction, so as to reduce the overall size of the thin film transistor 20.

In some other examples, one or more projections of the first active portion 211 in the direction Z perpendicular to the substrate can be arranged between two projections of the two adjacent second active portions 212 in the direction Z perpendicular to the substrate.

As shown in FIG. 1 to FIG. 3, in some optional embodiments, in the direction parallel to the plane where the substrate 10 is located and perpendicular to the extending direction of the first active portion 211, one second active portion 212 is arranged between two adjacent first active portions 211, and one first active portion 211 is arranged between two adjacent second active portions 212.

Exemplarily, a projection of one second active portion 212 in the direction Z perpendicular to the substrate is arranged between two projections of two adjacent first active portions 211 in the direction Z perpendicular to the substrate, and a projection of one first active portion 212 in the direction Z perpendicular to the substrate is arranged between two projections of two adjacent second active portions 211 in the direction Z perpendicular to the substrate. For example, the projections of the first active portion 211 and the second active portion 212 on the substrate 10 can be alternately arranged in the way of “first active portion 211—second active portion 212—first active portion 211—second active portion 211—second active portion 212 . . . ”

In these optional embodiments, it is beneficial to increasing the area of the side face of the active layer 21, increasing the distance between two adjacent active portions in the same layer, improving a heat-dissipating channel between two adjacent active portions in the same layer, and further improving the spatial utilization of the first active portion 211 and the second active portion 212 in the active layer 21.

As shown in FIG. 1 to FIG. 3, in some optional embodiments, the number of the first active portions 211 is different from the number of the second active portions 212, so that the applicable range of the length size and the width size of the active layer 21 can increase and the usage scenario of the thin film transistor 20 can increase.

Exemplarily, the number of the first active portions 211 is more than the number of the second active portions 212, or the number of the first active portions 211 is less than the number of the second active portions 212.

As shown in FIG. 1 to FIG. 3, in some optional embodiments, the number of the first active portions 211 is N, and the number of the second active portion 212 is N-1, N is a positive integer, and N≥2.

Exemplarily, the number of the first active portions 211 is 5, and the number of the second active portions 212 is 4. Optionally, N is 2, 3, 5, 8, 10 or other numerical values.

In some examples, in the direction parallel to the plane where the substrate 10 is located and perpendicular to the extending direction of the first active portion 211, one second active portion 212 is arranged between two adjacent first active portions 211, and one first active portion 211 is arranged between two adjacent second active portions 212. Moreover, the number of the second active portions 212 is one less than the number of the first active portions 211, so that the second active portions 212 can be arranged with a symmetry axis which is a central axis of the second active portion 212 in the middle. Of course, the first active portions 211 can also be arranged with the symmetry axis which is the central axis of the second active portion 212 in the middle, so that the difficulty of arranging the second active portions 212 can be reduced, the alignment accuracy of the first active portions 211 and the second active portions 212 during the arrangement process can be improved, and the spatial utilization of the first active portions 211 and the second active portions 212 can be improved.

In some examples, one or more second active portions 212 are arranged between two adjacent first active portions 211 in the direction parallel to the plane where the substrate 10 is located and perpendicular to the extending direction of the first active portion 211, so that an outer contour size of the first active portions 211 is an overall size of the active layer 21, so that it is conducive to detecting whether the overall size of the active layer 21 meets the design requirement during the manufacturing process of the first active portions 211, so as to improve the production yield and efficiency of the thin film transistor 20 in the manufacturing process.

As shown in FIG. 1 to FIG. 3, in some optional embodiments, the width of the first active portion 211 is equal to the width of the second active portion 212, so that a mask workpiece used in the manufacturing process of the first active portion 211 can be used as a mask workpiece used in the manufacturing process of the second active portion 212. In the specific patterned process engineering, only a certain displacement of the mask workpiece is required, which can effectively save the development cost of the mask workpiece and reduce the production cost.

The width of the first active portion 211 is a size perpendicular to the extending direction of the first active portion 211. It can be seen as described above that the first active portion 211 and the second active portion 212 extend in the first direction X, and the width of the first active portion 211 is the size of the first active portion 211 in the second direction Y.

As shown in FIG. 3, in some optional embodiments, the width of the second active portion 212 is larger than a distance between two adjacent first active portions 211.

Exemplarily, the size of the second active portion 212 in the second direction Y is larger than the distance between two adjacent first active portions 211 in the second direction Y. For example, the size of the second active portion 212 in the second direction Y is W1, the distance between two adjacent first active portions 211 in the second direction Y is W2, and W1>W2.

It can be understood that the two adjacent first active portions 211 refer to two first active portions 211 corresponding to two projections of the first active portions 211 adjacent to the projection of the second active portions 212 in the projections of the first active portions 211 and the projections of the second active portions 212 in the direction Z perpendicular to the substrate.

In the embodiments of the present application, according to the above arrangement, it is beneficial to reducing the possibility of reducing the area of the overlap region between the active layer 21 and gate 22 caused by the gap appearing in the projection of the active layer 21 formed by the first active portion 211 and the second active portion 212 in the direction perpendicular to the substrate 10, the heat-dissipating performance of the active layer 21 can be improved, the effective channel area of the active layer 21 can increase, and the load capacity of the thin film transistor 20 can be improved.

FIG. 4 shows a cross-sectional structural schematic view of an array substrate according to some embodiments of the present application

As shown in FIG. 3 and FIG. 4, in some optional embodiments, the projection of the second active portion 212 in the direction Z perpendicular to the substrate overlaps at least one of the projections of the two adjacent first active portions 211 in the direction Z perpendicular to the substrate.

In some examples, the projection of the second active portion 212 in the direction Z perpendicular to the substrate overlaps each of the projections of two adjacent first active portions 211 in the direction Z perpendicular to the substrate. In some other examples, the second active portion 212 overlaps with one of the projections of the two adjacent first active portions 211 in the direction Z perpendicular to the substrate, and is tangent to the other projection of the two adjacent first active portions 211 in the direction Z perpendicular to the substrate.

In these optional embodiments, according to the above arrangement, it is beneficial to reducing the requirement of the alignment accuracy between the second active portion 212 and the first active portion 211 during the manufacturing process, thereby reducing the possibility of forming a gap between the first active portion 211 and the second active portion 212 caused by the process error during the manufacturing process of the second active portion 212, reducing the possibility of a decrease in the effective channel area of the active layer 21 due to the process error, and improving the reliability of the thin film transistor 20.

As shown in FIG. 3 and FIG. 4, in some optional embodiments, the projection of the second active portion 212 in the direction Z perpendicular to the substrate overlaps each of the projections of two adjacent first active portions 211 in the direction Z perpendicular to the substrate, which can ensure that the second active portion 212 can fully cover a region between the two adjacent first active portions 211 during the manufacturing process, maximize the channel area of the active layer, further reduce the requirement of the alignment accuracy between the second active portion 212 and the first active portion 211 during the manufacturing process, reduce the manufacturing difficulty of the active layer 21, and improve the reliability of the thin film transistor 20.

As shown in FIG. 4, in some optional embodiments, an overlapping region between the projection of the second active portion 212 in the direction Z perpendicular to the substrate and one of the projections of two adjacent first active portions 211 in the direction perpendicular to the substrate 10 is a first overlapping portion, and an overlapping region between the projection of the second active portion 212 in the direction Z perpendicular to the substrate and the other of the projections of two adjacent first active portions 211 in the direction perpendicular to the substrate 10 is a second overlapping portion. The size of the first overlapping portion in the extending direction perpendicular to the first active portion 211 is larger than the size of the second overlapping portion perpendicular to the extending direction of the first active portion 211.

According to the above description, it can be seen that the size of the first overlapping portion in the extending direction perpendicular to the first active portion 211 is the size of the first overlapping portion in the second direction Y. By setting the size of the first overlapping portion in the second direction Y to be larger than the size of the second overlapping portion in the second direction Y, the second active portion 212 can use one of two adjacent first active portions 211 as an alignment reference during the manufacturing process, thereby simplifying the manufacturing difficulty of the second active portion 212, improving the detecting efficiency of the second active portion 212 in a detecting stage after manufacturing, and improving the production yield of the thin film transistor 20.

Exemplarily, a size of the first overlapping portion in the second direction Y is W3, a size of the second overlapping portion in the second direction Y is W4, and W3>W4.

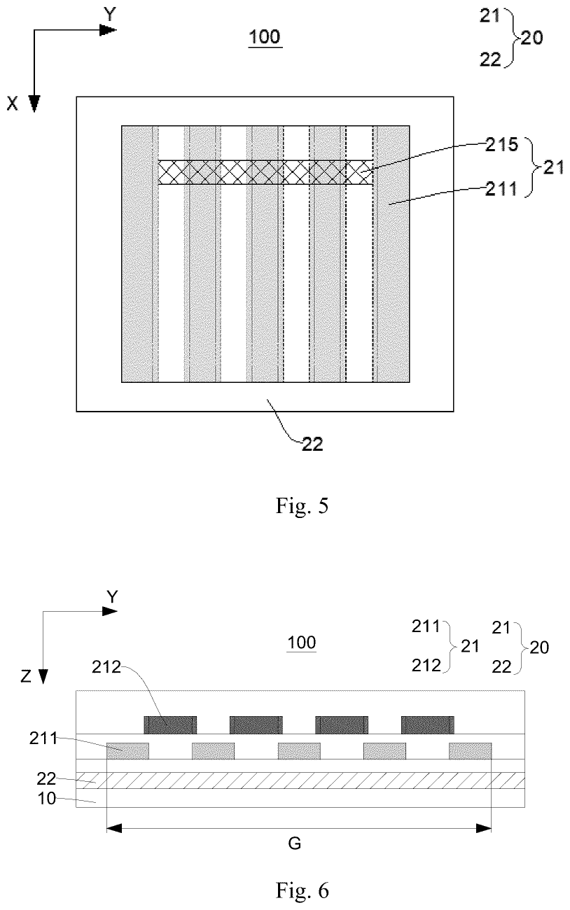

FIG. 5 shows a top structural schematic view of a first active portion of an array substrate according to some embodiments of the present application.

As shown in FIG. 5, in some optional embodiments, the active layer 21 further includes a connecting line 215, at least a portion of the plurality of first active portions 211 are connected through the connecting line 215, and an extending direction of the connecting line intersects with the extending direction of the first active portion 211.

Optionally, the plurality of the first active portions 211 can extend in the first direction X, and are spaced apart from one another in the second direction Y. The connecting line 215 can extend in the second direction Y. In some examples, the connecting line 215 can connect all the first active portions 211. In some other examples, the connecting line 215 connects a portion of the first active portions 211.

Optionally, at least a portion of the plurality of second active portions 212 can be connected through the connecting line 215.

Furthermore, the plurality of first active portions 211 and the plurality of second active portions 212 can be connected through the connecting line 215.

Optionally, the connecting line 215 and the first active portions 211 can be arranged on the same layer; alternatively, the connecting line 215 and the second active portions 212 can be arranged on the same layer; alternatively, the connecting line 215, the first active portion 211 and the second active portion 212 are respectively arranged at different layers.

In these optional embodiments, according to the above arrangement, the connection between the source-drain electrode 23 and the plurality of first active portions 211 can be achieved by only connecting the source-drain electrode 23 with the connecting line 215, thereby reducing the number of connection structures between the source-drain electrode 23 and the plurality of first active portions 211, and simplifying the overall structure of the thin film transistor 20.

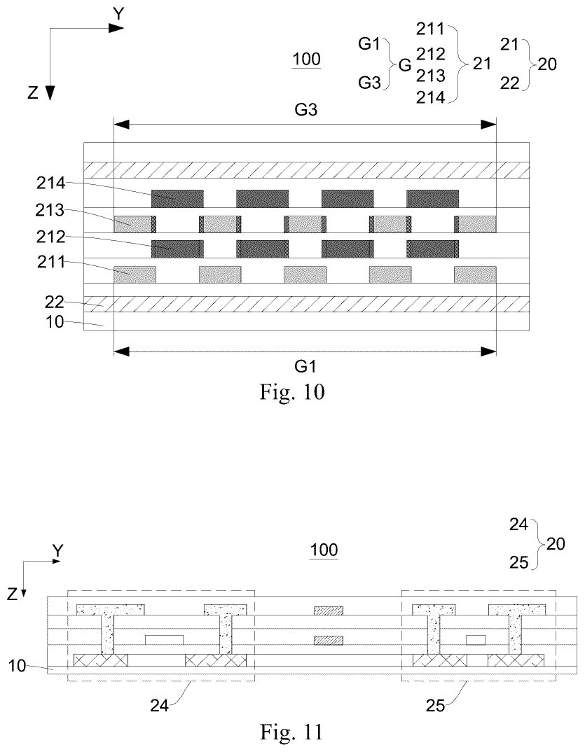

FIG. 6 shows a cross-sectional structural schematic view of another array substrate according to some embodiments of the present application. It should be noted that, in FIG. 6, FIG. 9 and FIG. 10 mentioned below, taking FIG. 6 as an example, there are two different filling patterns in the second active portion 212. A pattern filled in the second active portion 212 in the overlapping region between the first active portion 211 and the second active portion 212 is different from a pattern filled in the second active portion 212 in the non-overlapping region between the first active portion 211 and the second active portion 212. Taking FIG. 10 as an example, there are two different filling patterns in a third active portion 213. A pattern filled in the third active portion 213 in an overlapping region between the third active portion 213 and a fourth active portion 214 is different from a pattern filled the third active portion 213 in a non-overlapping region between the third active portion 213 and the fourth active portion 214.

As shown in FIG. 6, in some optional embodiments, the first active portion 211 and the second active portion 212 jointly form an active layer effective region G, and the active layer effective region overlaps the gate 22 in the direction Z perpendicular to the substrate.

After applying the voltage to the gate 22, the active layer 21 forms a channel for the carrier migration. Specifically, when the thin film transistor 20 operates, the voltage is applied to the gate 22, which generates the electric field. A direction of the electric field is from the gate 22 towards a surface of the channel region of the active layer 21 (i.e. a surface of the first active portion 211 opposite to the gate 22, and a surface of the second active portion 212 opposite to the gate 22), and induced charges are generated at the surface. As the voltage of the gate 22 increases, the surface of the channel region will be transformed from a depletion layer to an electron accumulation layer to form an inversion layer. When the voltage of the gate 22 reaches a threshold voltage, a voltage is applied to a region of the active layer 21 in contact with the source-drain electrode 23, and the carriers pass through the channel region. Herein, the surface of the channel region is the active layer effective region G.

In some examples, a projection of the active layer effective region G in the direction Z perpendicular to the substrate coincides with the projection of the gate 22 in the direction Z perpendicular to the substrate. In some other examples, the projection of the active layer effective region G in the direction Z perpendicular to the substrate is located within the projection of the gate 22 in the direction Z perpendicular to the substrate.

In these optional embodiments, the active layer effective region G overlaps the gate 22, so that an area of a region of the active layer 21 that is not face to the gate 22 can be reduced, the possibility of increase in the resistance of active layer 21 due to no carrier passing through in a portion of region of the active layer 21 can be reduced, and the possibility of decrease in the load capacity of the thin film transistor 20 can be further reduced.

As shown in FIG. 6, in some optional embodiments, the gate 22 is located between the substrate 10 and the active layer 21, and the projection of the active layer effective region G in the direction perpendicular to the substrate 10 is located within the projection of the gate 22 in the direction perpendicular to the substrate 10.

The gate 22 is located between the substrate and the active layer 21, and the thin film transistor 20 may be a bottom gate type of the thin film transistor.

The active layer effective region G may be a side of the active layer facing the substrate 10. The projection of the first active portion 211 in the direction Z perpendicular to the substrate does not overlap the projection of the second active portion 212 in the direction Z perpendicular to the substrate.

In these optional embodiments, by setting the thin-film transistor 20 as the bottom gate type of the thin-film transistor 20, the thin-film transistor can be adapted to the array substrate 100 including the substrate 10 which is made of a transparent material, which can reduce the risk of the light passing through the substrate and illuminating the active layer 21, and improve the applicability range of the thin film transistor 20.

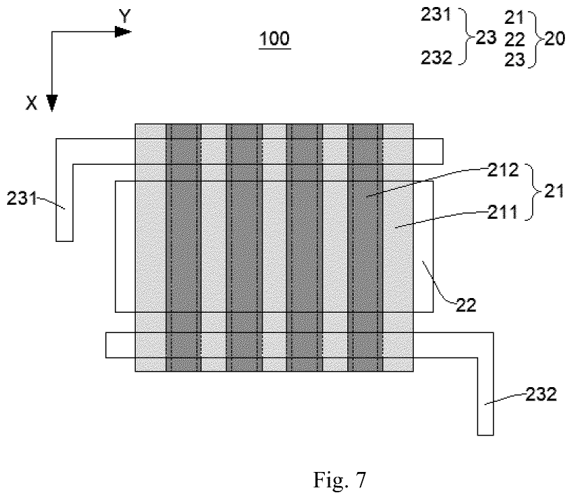

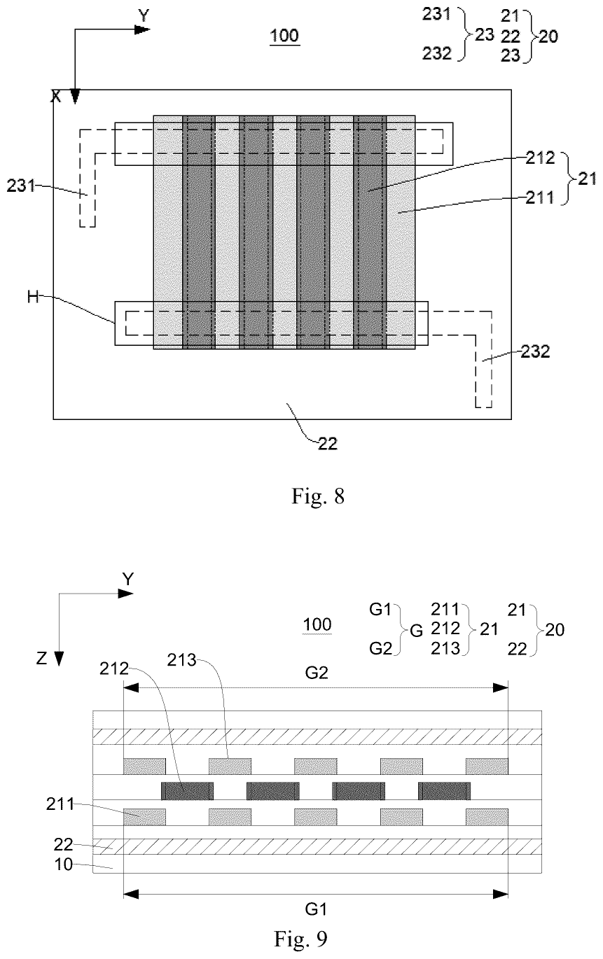

FIG. 7 shows a cross-sectional structural schematic view of another array substrate according to some embodiments of the present application; FIG. 8 shows a cross-sectional structural schematic view of another array substrate according to some embodiments of the present application.

As shown in FIG. 7 and FIG. 8, in some optional embodiments, the gate 22 is located on a side of the active layer 21 away from the substrate 10. The projection of the gate 22 in the direction perpendicular to the substrate is located within the active layer effective region G. Alternatively, the gate 22 includes an avoiding hole H, the projection of the source-drain electrode 23 in the direction Z perpendicular to the substrate is located within a projection of the avoiding hole H in the direction Z perpendicular to the substrate, and the projection of the active layer effective region G in the direction perpendicular to the substrate 10 is located within the projection of the gate 22 in the direction perpendicular to the substrate.

The gate is located on a side of the active layer 21 away from the substrate 10, and the thin film transistor 20 may be a top gate type of the thin film transistor.

The active layer effective region G may be the non-overlapping region between the projection of the first active portion 211 in the direction Z perpendicular to the substrate and the projection of the second active portion 212 in the direction Z perpendicular to the substrate on the side of the active layer away from the substrate 10.

In some embodiments, the projection of the gate 22 in the direction perpendicular to the substrate 10 is located within the active layer effective region G, that is, a projection area of the gate 22 in the direction perpendicular to substrate 10 is smaller than an area of the active layer effective region G.

In some embodiments, since the layer structure of the thin film transistor 20 includes the active layer 21, the gate 22 and the source-drain electrode 23 which are sequentially arranged in a direction away from the substrate 10, the gate is insulated from the source-drain electrode 23. The source-drain electrode needs to be connected to the active layer 21 through the avoiding hole H in the gate 22, so as to reduce the possibility of the failure of the thin film transistor 20 caused by the contact between the gate 22 and the source-drain electrode 23.

FIG. 9 shows a cross-sectional structural schematic view of another array substrate according to some embodiments of the present application; FIG. 10 shows a cross-sectional structural schematic view of another array substrate according to some embodiments of the present application.

As shown in FIG. 9 and FIG. 10, in some optional embodiments, the gate 22 includes a first gate 221 and a second gate 222. The first gate is located between the substrate 10 and the active layer 21, and the second gate 222 is located on the side of the active layer 21 away from the substrate 10. The projection of the active layer effective region G in the direction perpendicular to the substrate 10 at least partially overlaps at least one of projections of the first gate 221 and the second gate 222 in the direction perpendicular to the substrate 10.

The gate 22 includes the first gate 221 and the second gate 222. The first gate is located between the substrate 10 and the active layer 21, and the second gate 222 is located on the side of the active layer away from the substrate 10. The thin film transistor 20 may be a dual-gate type of the thin film transistor.

The active layer effective region G may include the non-overlapping region between the projection of the first active portion 211 in the direction Z perpendicular to the substrate and the projection of the second active portion 212 in the direction Z perpendicular to the substrate on the side of the active layer facing the substrate, and the non-overlapping region between the projection of the first active portion 211 in the direction Z perpendicular to the substrate and the projection of the second active portion 212 away from the side of the substrate 10 on the side of the active layer 21 away from the substrate.

In some examples, the projection of the active layer effective region G in the direction perpendicular to the substrate 10 at least partially overlaps a projection of the first gate 221 in the direction perpendicular to the substrate. In some other examples, the projection of the active layer effective region G in the direction perpendicular to the substrate 10 at least partially overlaps the projection of the second gate 222 in the direction perpendicular to the substrate. In some other examples, the projection of the active layer effective region G in the direction perpendicular to the substrate 10 at least partially overlaps the projection of the first gate 221 in the direction perpendicular to the substrate, and the projection of the active layer effective region G in the direction perpendicular to the substrate 10 at least partially overlaps the projection of the second gate 222 in the direction perpendicular to the substrate.

In these optional embodiments, by arranging the dual-gate type of the thin film transistor 20, the control of the thin film transistor 20 can be more flexible, the linear performance of the thin film transistor 20 can be improved, and the overall size of the thin film transistor can be reduced.

As shown in FIG. 9, in some optional embodiments, the active layer 21 further includes at least one third active portion 213. The first active part 211, the second active part 212 and the third active part 213 are sequentially stacked in the direction away from the substrate 10. Herein, the first active portion 211 and the second active portion 212 jointly form a first active layer effective region G1, and the second active portion 212 and the third active portion 213 jointly form a second active layer effective region G2. A projection of the first active layer effective region G1 in the direction perpendicular to the substrate 10 is located within the projection of the first gate 221 in the direction perpendicular to the substrate, and a projection of the second active layer effective region G2 in the direction perpendicular to the substrate 10 is located within the projection of the second gate 222 in the direction perpendicular to the substrate.

It can be understood that the first active portion 211, the second active portion 212 and the third active portion 213 are insulated from one another.

The first active layer effective region G1 may include a non-overlapping region between the projection of the first active portion 211 in the direction Z perpendicular to the substrate and the projection of the second active portion 212 in the direction Z perpendicular to the substrate on the side of the active layer facing the substrate 10.

The second active layer effective region G2 may include a non-overlapping region between the projection of the second active portion 212 in the direction Z perpendicular to the substrate and the projection of the third active portion 213 in the direction Z perpendicular to the substrate on the side of the active layer away from the substrate 10.

Optionally, at least one second active portion 212 is arranged between two adjacent third active portions 213 in the direction Z perpendicular to the substrate.

Optionally, the number of the third active portions 213 may be the same as the number of the first active portions 211, or may be different from the number of the first active portions 211.

Optionally, the number of the third active portions 213 may be the same as the number of the second active portions 212, or may be different from the number of the second active portions 212.

Optionally, the projection of the first active portion 211 in the direction perpendicular to the substrate 10 at least partially overlaps the projection of the third active portion 213 in the direction perpendicular to the substrate.

It can be understood that the projection of the second active portion 212 in the direction Z perpendicular to the substrate does not overlap the projection of the third active portion 213 in the direction Z perpendicular to the substrate, at least partially.

In the embodiments of the present application, according to the above arrangement, the heat-dissipating area of the active layer 21 can further increase, the sizes of the active layer in the length direction and the width direction can be reduced, the effective channel area of the active layer 21 can increase, the load performance of the thin film transistor 20 can be improved, and the display effect of the display panel 200 can be improved.

As shown in FIG. 10, in some optional embodiments, the active layer 21 further includes at least one third active portion 213 and at least one fourth active portion 214. The first active portion 211, the second active portion 212, the third active portion 213 and the fourth active portion 214 are sequentially stacked in the direction away from the substrate 10. Herein, the first active portion 211 and the second active portion 212 jointly form the first active layer effective region G1, the third active portion 213 and the fourth active portion 214 jointly form a third active layer effective region G3. The projection of the first active layer effective region G1 in the direction perpendicular to the substrate 10 is located within the projection of the first gate 221 in the direction perpendicular to the substrate, and a projection of the third active layer effective region G3 in the direction perpendicular to the substrate 10 is located within the projection of the second gate 222 in the direction perpendicular to the substrate.

It can be understood that the first active portion 211, the second active portion 212, the third active portion 213 and the fourth active portion 214 are insulated from one another.

The first active layer effective region G1 may include a non-overlapping region between the projection of the first active portion 211 in the direction Z perpendicular to the substrate and the projection of the second active portion 212 in the direction Z perpendicular to the substrate on the side of the active layer facing the substrate 10.

The third active layer effective region G3 may include a non-overlapping region between the projection of the third active portion 213 in the direction Z perpendicular to the substrate and a projection of the fourth active portion 214 in the direction Z perpendicular to the substrate on the side of the active layer away from the substrate 10.

Optionally, at least one fourth active portion 214 is arranged between two adjacent third active portions 213 in the direction Z perpendicular to the substrate.

Optionally, the number of the third active portions 213 may be the same as the number of the first active portions 211, or may be different from the number of the first active portions 211.

Optionally, the number of the fourth active portions 214 may be the same as the number of the second active portions 212, or may be different from the number of the second active portions 212.

Optionally, the projection of the first active portion 211 in the direction perpendicular to the substrate 10 at least partially overlaps the projection of the third active portion 213 in the direction perpendicular to the substrate.

Optionally, the projection of the second active portion 212 in the direction perpendicular to the substrate 10 at least partially overlaps the projection of the fourth active portion 214 in the direction perpendicular to the substrate.

It can be understood that the projection of the third active portion 213 in the direction perpendicular to the substrate does not overlap the projection of the fourth active portion 214 in the direction perpendicular to the substrate, at least partially.

In the embodiments of the present application, according to the above arrangement, the heat-dissipating area of the active layer 21 can further increase, and the thin film transistor 20 can work normally when the first gate 221 and the second gate 222 can be jointly controlled or individually controlled according to the design requirement, so as to improve the linear performance of the thin film transistor 20 and enhance the control flexibility of the thin film transistor.

In some optional embodiments, the indium content of one of the first active portion 211 and the second active portion 212 close to the gate 22 is less than the indium content of the other one.

Taking the layer structure in the thin film transistor 20 including the gate 22, the first active portion 211, the second active portion 212 and the source-drain electrode 23 in the direction away from substrate 10 as an example, the indium content of the first active portion 211 is lower than the indium content of the second active portion 212.

In these optional embodiments, by setting the indium content of the active portion close to the gate 22 to be less than the indium content of the active portion far away from the gate 22, the mobility of the active portion close to the gate 22 is lower than the mobility of the active portion far away from the gate, so as to balance the conductivity performances of the first active portion 211 and the second active portion 212.

In some optional embodiments, the active layer 21 includes a channel region and a doping region, the doping region is connected to the source-drain electrode 23, and a doping concentration in the doping region of one of the first active region 211 and the second active region 212 close to the gate 22 is lower than a doping concentration in the doping region of the other one.

The doping region is connected to the source-drain electrode 23, and includes a doping region of the source 231 and a doping region of the drain 232. The doping region of the source is connected to the source, and the doping region of the drain 232 is connected to the drain 232. The channel region is located between the doping region of the source 231 and the doping region of the drain, and the doping region can be arranged opposite to the gate 22.

Taking the layer structure in the thin film transistor 20 including the gate 22, the first active portion 211, the second active portion 212 and the source-drain electrode 23 in the direction away from substrate 10 as an example, the doping concentration in the doping region of the first active portion 211 is lower than the doping concentration in the doping region of the second active portion 212, so as to increase the voltage applied by the gate 22 when the surface of the channel region of the first active portion 211 transforms from the depletion layer to the electron accumulation layer to form the inversion layer, increase the threshold voltage that the first active portion 211 can withstand, and balance the threshold voltages required by the first active portion and the second active portion 212.

FIG. 11 shows a cross-sectional structural schematic view of another array substrate according to some embodiments of the present application.

As shown in FIG. 11, in some optional embodiments, the thin film transistor 20 includes a first thin film transistor 24 and a second thin film transistor 25. A size of the active layer 21 of the first thin film transistor in the width direction is different from a size of the active layer of the second thin film transistor 25 in the width direction. The width direction intersects with the direction Z perpendicular to the substrate.

Optionally, the width direction is the second direction Y in the drawings.

In some examples, the size of the active layer 21 of the first thin film transistor 24 in the width direction is smaller than a size of the second thin film transistor 25 in the width direction. In some other examples, the size of the active layer 21 of the first thin film transistor 24 in the width direction is larger than the size of the second thin film transistor 25 in the width direction.

It can be understood that each of the first thin film transistor 24 and the second thin film transistor 25 may include the first active portion 211 and the second active portion 212 located in different layers. A width size of the first thin film transistor 24 or a width size of the second thin film transistor 25 can be achieved by arranging different numbers of the first active portions 211 and the second active portions 212. Of course, each of the first thin film transistor 24 and the second thin film transistor 25 may also include the third active portion 213 and/or the fourth active portion 214. Alternatively, the active layer 21 in at least one of the first thin film transistor 24 and the second thin film transistor 25 can be a whole-layer-continuous structure.

In these optional embodiments, according to the above arrangement, the applicability range of the thin film transistor 20 can increase, and the thin film transistor can be applied in the circuits in different scenarios.

As shown in FIG. 11, in some optional embodiments, the number of the first active portion 211 of the first thin film transistor 24 is m11, and the number of the second active portion 212 of the first thin film transistor 24 is m12; the number of the first active portion 211 of the second thin film transistor 25 is m21, and the number of the second active portion 212 of the second thin film transistor 25 is m22; and m11+m12≠m21+m22.

Exemplarily, m11+m12>m21+m22; alternatively, m11+m12<m21+m22.

It can be understood that the number of m11 may be more than, less than or even equal to the number of m21; the number of m12 may be more than, less than or even equal to the number of m22. The embodiments of the present application does not limit these and can ensure that m11+m12≠m21+m22.

In these optional embodiments, the width size of the first thin film transistor 24 and the width size of the second thin film transistor 25 can be adjusted by adjusting the number of the first active portions 211 and the number of the second active portions 212, thereby simplifying the difficulty of controlling the width sizes of the first thin film transistor 24 and the second thin film transistor, and reducing the production difficulty of the first thin film transistor 24 and the second thin film transistor 25.

Alternatively, in some other examples, m11+m12=m21+m22.

As shown in FIG. 11, in some optional embodiments, m11>m21, and/or m12>m22.

In some examples, m11>m21. In some other examples, m12>m22. In some other examples, m11>m21, and m12>m22, that is, (m11-m21)*(m12-m22)>0.

In these optional embodiments, by adjusting the number of the first active portions 211 and the second active portions 212 in the first thin film transistor 24 and the second thin film transistor 25, an average thickness of the insulating layer for the gate 22 between the gate 22 and the active layer 21 can be changed, so that the thickness of the insulating layer for the gate 22 in the first thin film transistor 24 is smaller than the thickness of the insulating layer for the gate in the second thin film transistor 25, thereby reducing the leakage current of the second thin film transistor 25, adjusting the performance of the second thin film transistor, and improving the stability of the thin film transistor 20.

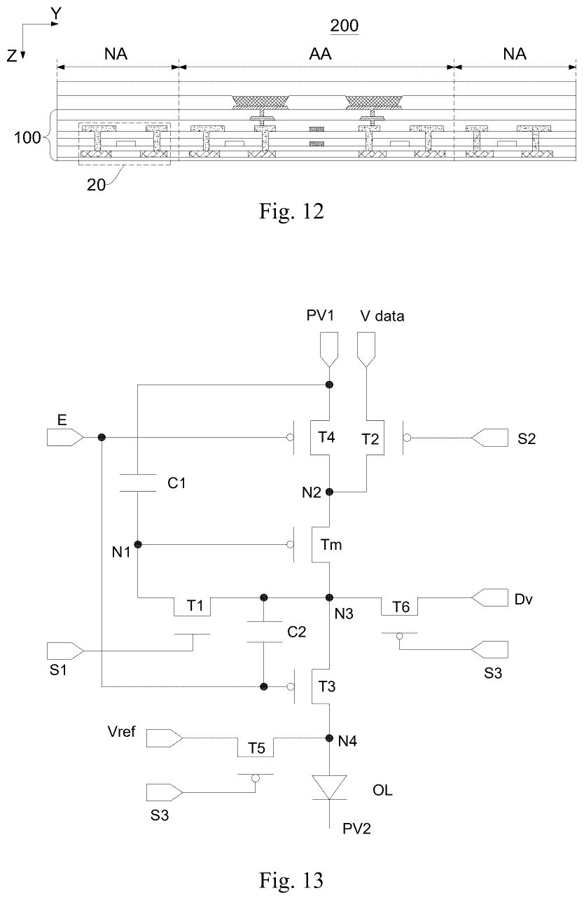

FIG. 12 shows a cross-sectional structural schematic view of a display panel according to some embodiments of the present application.

As shown in FIG. 12, in some optional embodiments, the array substrate 100 includes a first region AA and a second region NA surrounding at least a portion of the first region AA. The array substrate 100 further includes a driving circuit at least located in the first region and a control circuit at least located in the second region NA. The control circuit includes the thin film transistor 20, and/or, the driving circuit includes the thin film transistor.

The array substrate 100 can be applied to the display panel 200. The display panel further includes a light-emitting unit OL. The circuits in the array substrate 100 can be electrically connected to the light-emitting unit. Exemplarily, the driving circuit in the array substrate 100 can increase the driving current for the light-emitting unit OL. The control circuit in the array substrate 100 can provide a scanning control signal or a light-emitting control information to the driving circuit.

Optionally, the second region NA may surround the first region AA. Alternatively, the second region may surround a portion of the first region.

In some examples, the control circuit includes the thin film transistor 20. In some other examples, the driving circuit includes the thin film transistor. In some other examples, each of the control circuit and the driving circuit includes the thin film transistor 20.

By arranging the thin film transistor 20 in the control circuit and/or the driving circuit, the high load required by the control circuit and/or driving circuit can increase, the current value that the control circuit and/or driving circuit can withstand can increase, and the control sensitivity of the control circuit and/or driving circuit can be improved.

FIG. 13 shows a structural schematic view of a driving circuit of a display panel according to some embodiments of the present application.

As shown in FIG. 13, in some optional embodiments, the driving circuit includes a first type transistor, a first power signal terminal PV1 and a second power signal terminal PV2. The first type transistor is connected in series between the first power signal terminal PV1 and the second power signal terminal PV2, and the first type transistor includes the thin film transistor 20.

In some embodiments, the driving circuit is electrically connected to the light-emitting unit OL. FIG. 13 further shows the light-emitting unit. The driving circuit further includes a first capacitor C1 and a second capacitor C2. The first capacitor is connected between the first power signal terminal PV1 and the gate 22 of a driving transistor Tm, and used to store the signal transmitted to the gate of the driving transistor. The driving circuit shown in the figure includes a data-writing module, a light-emitting control module, a threshold-compensating module, a reset module for the light-emitting unit OL, a bias adjustment module, a first node N1, a second node N2, a third node N3 and a fourth node N4. The figure further shows a light-emitting control terminal, a first scanning signal terminal, a second scanning signal terminal, a third scanning signal terminal, a data signal terminal, a reset signal terminal and a bias adjustment signal terminal.

Optionally, as shown in FIG. 13, a control terminal (gate 22) of the driving transistor Tm is connected to the first node N1, a first electrode of the driving transistor Tm is connected to the second node N2, and a second electrode of the driving transistor is connected to the third node N3. A first terminal of the data-writing module is connected to the data signal terminal, a second terminal of the data-writing module is connected to the second node N2, a control terminal of the data-writing module is connected to the second scanning signal terminal, and the data-writing module is used to write the data signal. A first terminal of the threshold-compensating module is connected to the first node N1, the second terminal of the threshold-compensating module is connected to the third node N3, and a control terminal of the threshold-compensating module is connected to the first scanning signal terminal.

Optionally, the light-emitting control module includes a first light-emitting control module and a second light-emitting control module. A first terminal of the first light-emitting control module is connected to the first power signal terminal PV1, a second terminal of the first light-emitting control module is connected to the second node N2, a first terminal of the second light-emitting control module is connected to the third node N3, and a second terminal of the second light-emitting control module is connected to the fourth node N4. Each of the control terminal of the first light-emitting control module and the second light-emitting control module are connected to the light-emitting control terminal, and the light-emitting control module is used to control whether the light-emitting unit OL emits light.

Referring to FIG. 13, optionally, the driving circuit in the display panel 200 further includes the bias adjustment module. A first terminal of the bias adjustment module is connected to the bias adjustment signal terminal, a second terminal of the bias adjustment module is connected to the third node N3, a control terminal of the bias adjustment module is connected to the third scanning signal terminal, and the bias adjustment module is used to adjust a bias state of the driving transistor Tm.

Optionally, the driving circuit further includes a storage capacitor. A first terminal of the storage capacitor is connected to the first power signal terminal PV1, a second terminal of the storage capacitor is connected to the first node N1, and the storage capacitor is used to stabilize a potential of the gate 22 of the driving transistor Tm.

The gate of the driving transistor Tm is electrically connected to the first node N1, a first terminal of the driving transistor Tm is electrically connected to the second node N2, a second terminal of the driving transistor is electrically connected to the third node N3, a first terminal of the threshold-compensating transistor T1 is electrically connected to the third node, a second terminal of the threshold-compensating transistor T1 is electrically connected to the first node N1, and the gate 22 of the threshold-compensating transistor is electrically connected to the first scanning signal terminal. A pixel circuit includes a data-writing transistor T2, a second scanning signal terminal and a data signal terminal. The gate 22 of the data-writing transistor T2 is electrically connected to the second scanning signal terminal, the first terminal of the data-writing transistor T2 is electrically connected to the data signal terminal, and the second terminal of the data-writing transistor is electrically connected to the second node N2.

The driving circuit further includes a first light-emitting control transistor T3, a second light-emitting control transistor T4, a reset transistor T5 and a bias adjustment transistor T6. The gate 22 of the first light-emitting control transistor T3 and the gate 22 of the second light-emitting control transistor T4 are both electrically connected to the light-emitting control terminal. A first terminal of the first light-emitting control transistor T3 is electrically connected to the third node N3, and a second terminal of the first light-emitting control transistor is electrically connected to an anode of the light-emitting unit OL. A first terminal of the second light-emitting control transistor T4 is electrically connected to the first power signal terminal PV1, and a second terminal of the second light-emitting control transistor T4 is electrically connected to the second node N2. The gate 22 of the reset transistor T5 is electrically connected to the third scanning signal terminal, a first terminal of the reset transistor T5 is electrically connected to the reset signal terminal, and a second terminal of the reset transistor is electrically connected to the anode of the light-emitting unit OL. A cathode of the light-emitting unit is electrically connected to the second power signal terminal PV2. The gate 22 of the bias adjustment transistor T6 is electrically connected to the third scanning signal terminal, a first terminal of bias adjustment transistor T6 is electrically connected to the bias signal terminal, and a second terminal of the bias adjustment transistor T6 is electrically connected to the third node N3. Herein, the bias adjustment transistor is used to adjust the bias state of the driving transistor Tm. In addition, as shown in the embodiment in the figure, the gate 22 of the bias adjustment transistor T6 and the gate of the reset transistor T5 are both connected to the third scanning signal terminal, that is, the light-emitting unit OL is reset while the bias adjustment is performed on the driving transistor Tm. Optionally, in another embodiment, the gate 22 of the bias adjustment transistor T6 and the gate of the reset transistor T5 are connected to different signal terminals, respectively, so that the bias adjustment for the driving transistor Tm and the resetting for the light-emitting unit OL can be achieved at different moments.

In some embodiments, the first type transistor may be the driving transistor Tm, the first light-emitting control transistor T3 or the second light-emitting control transistor T4. In some other examples, the first type transistor may be the threshold-compensating transistor T1 or the reset transistor T5. It can be understood that when the first type transistor is the driving transistor Tm, the driving transistor includes the first active portion 211 and the second active portion 212 located in different layers, respectively.

In this embodiment, the circuit structure is merely for the illustrative purpose, not intended as a limitation of the present application, and merely used to illustrate the position of the first type transistor in the driving circuit in the embodiments of the present application. Herein, the first type transistor is connected between the first power signal terminal PV1 and the second power signal terminal PV2. The first type transistor can carry the high load current to ensure the sensitivity of controlling the light-emitting unit OL.

In some optional embodiments, the driving circuit further includes a second type transistor, and a width-to-length ratio of the first type transistor is larger than a width-to-length ratio of the second type transistor.

As mentioned above, the first type transistor may include the first transistor M1, and optionally, may further include the second transistor M2. The second type transistor may include the second transistor, and optionally, may further include the thin film transistor 20 including the active layer 21 with the whole layer continuous structure. The embodiments of the present application do not limit this and ensure that a width-to-length ratio of the first type transistor is larger than that of the second type transistor.

According to the above arrangement, when the array substrate 100 is provided with different types of thin film transistors 20, the thin film transistors 20 with different width-to-length ratios can be selected in targeted according to the design requirements, so as to reduce the redundant design requirements for the thin film transistors.

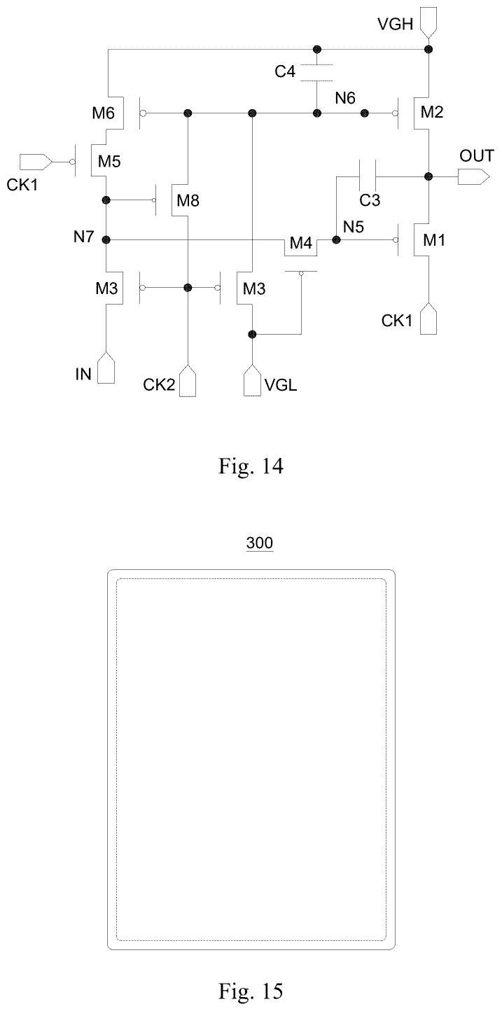

FIG. 14 shows a structural schematic view of a control circuit of a display panel according to some embodiments of the present application.

As shown in FIG. 14, in some optional embodiments, the control circuit includes an output terminal OUT and an output module. The output module includes the first transistor M1 and the second transistor M2. A first terminal of the first transistor is electrically connected to a clock signal terminal CK1, a first terminal of the second transistor is electrically connected to a first level signal terminal VGH, and a second terminal of the first transistor M1 and a second terminal of the second transistor M2 are electrically connected to the output terminal OUT. At least one of the first transistor M1 and the second transistor is the thin film transistor 20.

As shown in FIG. 14, the control circuit includes the output terminal OUT and the output module. The control circuit includes a third capacitor C3 and a fourth capacitor C4. The third capacitor is connected between the control terminal of the output module (i.e. the fifth node N5 in the circuit) and the output terminal OUT. The output module includes the first transistor M1 and the second transistor M2. The control terminal of the first transistor M1 is electrically connected to the fifth node N5, the first terminal of the first transistor M1 is electrically connected to the clock signal terminal CK1, and the second terminal of the first transistor is electrically connected to the output terminal OUT. The control terminal of the second transistor M2 is electrically connected to a sixth node N6, the first terminal of the second transistor M2 is electrically connected to the first level signal terminal VGH, and the second terminal of the second transistor is electrically connected to the output terminal OUT. The figure further illustrates a first input module, a second input module, a first protection module and second protection module in the driving circuit. Among them, the first input module includes a third transistor M3 and a fourth transistor M4. A control terminal of the third transistor M3 is electrically connected to the clock signal end CK1, a first terminal of the third transistor M3 is electrically connected to the input terminal, and a second terminal of the third transistor is electrically connected to a seventh node N7. A control terminal of the fourth transistor M4 is electrically connected to the second level signal terminal VGL, a first terminal of the fourth transistor M4 is electrically connected to the seventh node N7, and a second terminal of the fourth transistor is electrically connected to the fifth node N5. The first input module is used to write the voltage signal to the fifth node. The second input module includes a seventh transistor M7. A control terminal of the seventh transistor is electrically connected to the clock signal terminal CK1. A first terminal of the seventh transistor M7 is electrically connected to the second level signal terminal VGL. A second terminal of the seventh transistor is electrically connected to the sixth node N6. The second input module is used to write the voltage signal to the sixth node. The first protection module includes a fifth transistor M5 and a sixth transistor M6. A control terminal of the fifth transistor M5 is electrically connected to the clock signal end CK1, a first terminal of the fifth transistor M5 is electrically connected to a second terminal of the sixth transistor M6, and a second terminal of the fifth transistor is electrically connected to the seventh node N7. A control terminal of the sixth transistor M6 is electrically connected to the sixth node N6, and a first terminal of the sixth transistor is electrically connected to the first level signal end VGH. The first protection module is used to control and provide the high-level signal to the fifth node N5 when the sixth node N6 is at the low level, so as to achieve the opposite potentials between the fifth node and the sixth node N6. The second protection module includes an eighth transistor M8. A control terminal of the eighth transistor is electrically connected to the seventh node N7, a first terminal of the eighth transistor M8 is electrically connected to the clock signal terminal CK1, and a second terminal of the eighth transistor is electrically connected to the sixth node N6. The second protection module is used to provide the high-level signal to the sixth node N6 when the fifth node N5 is at the low level, so as to achieve the opposite potential between the fifth node N5 and the sixth node.

In this embodiment, the circuit structure is merely for the illustrative purpose, not intended as a limitation of the present application, and merely used to illustrate the positions of the first transistor M1 and the second transistor M2 in the control circuit in the embodiments of the present application.

In some examples, the first transistor M1 is the thin film transistor 20. In some other examples, the second transistor M2 is the thin film transistor. In some other examples, each of the first transistor M1 and the second transistor M2 is the thin film transistors 20.

In a second aspect, the embodiments of the present application further provide a display panel including the array substrate according to any one of the embodiments as described above.

Since the display panel provided by the embodiments of the present application includes the array substrate according to any one of the embodiments as described above, the display panel provided by the embodiments of the present application has the beneficial effects of the array substrate according to any one of the embodiments as described above, which will not be repeated here.

FIG. 15 shows a top structural schematic view of a display device according to some embodiments of the present application.

In a third aspect, the embodiments of the present application further provides a display device including the display panel according to any one of the embodiments as described above.

Although the present application has been described with reference to the preferred embodiments, various modifications may be made and equivalents may be substituted for parts of the embodiments without departing from the scope of the present application. In particular, as long as there is no structural conflict, the technical features mentioned in the embodiments can be combined in any manner. The present application is not limited to the specific embodiments disclosed herein, but includes all technical solutions falling within the scope of the claims.

What is claimed is:

1. An array substrate, characterized by comprising:
a substrate; and
a thin film transistor, located on a side of the substrate, the thin film transistor comprising an active layer, a gate, and a source-drain electrode, the active layer comprising at least one first active portion and at least one second active portion, the first active portion and the second active portion being arranged in different layers, a projection of the first active portion in a direction perpendicular to the substrate and a projection of the second active portion in the direction perpendicular to the substrate being at least partially non-overlapping, the source-drain electrode being located on a side of the active layer away from the substrate, and the first active portion and the second active portion being connected to the source-drain electrode;
a non-overlapping region between the first active portion and the second active portion at least partially overlapping the gate in the direction perpendicular to the substrate; and
the first active portion and the second active portion comprising an oxide semiconductor.

2. The array substrate according to claim 1, wherein at least one second active portion is arranged between two adjacent first active portions in a direction parallel to a plane where the substrate is located and perpendicular to an extending direction of the first active portion.

3. The array substrate according to claim 1, wherein a number of the first active portion is different from a number of the second active portion;
the number of the first active portions is N, the number of the second active portion is N-1, N is a positive integer, and N≥2.

4. The array substrate according to claim 1, wherein a width of the first active portion is equal to a width of the second active portion; and
the width of the second active portion is larger than a distance between two adjacent first active portions.

5. The array substrate according to claim 4, wherein the projection of the second active portion in the direction perpendicular to the substrate overlaps at least one of projections of the two adjacent first active portions in the direction perpendicular to the substrate; or
the projection of the second active portion in the direction perpendicular to the substrate overlaps each of the projections of the two adjacent first active portions in the direction perpendicular to the substrate.

6. The array substrate according to claim 4, wherein an overlapping region between the projection of the second active portion in the direction perpendicular to the substrate and one of the projections of the two adjacent first active portions in the direction perpendicular to the substrate is a first overlapping portion, an overlapping region between the projection of the second active portion in the direction perpendicular to the substrate and another of the projections of the two adjacent first active portions in the direction perpendicular to the substrate is a second overlapping portion, and a size of the first overlapping portion in a direction perpendicular to an extending direction of the first active portion is larger than a size of the second overlapping portion in the direction perpendicular to the extending direction of the first active portion.

7. The array substrate according to claim 1, wherein the active layer further comprises a connecting line, at least parts of a plurality of first active portions are connected through the connecting line, and an extending direction of the connecting line intersects with an extending direction of the first active portions.

8. The array substrate according to claim 1, wherein the first active portion and the second active portion jointly form an active layer effective region, and the active layer effective region overlaps the gate in the direction perpendicular to the substrate; and
the gate is located between the substrate and the active layer, and a projection of the active layer effective region in the direction perpendicular to the substrate is located within a projection of the gate in the direction perpendicular to the substrate.

9. The array substrate according to claim 8, wherein the gate is located on a side of the active layer away from the substrate;
the projection of the gate in the direction perpendicular to the substrate is located within the active layer effective region; or
the gate comprises an avoiding hole, a projection of the source-drain electrode in the direction perpendicular to the substrate is located within a projection of the avoiding hole in the direction perpendicular to the substrate, and the projection of the active layer effective region in the direction perpendicular to the substrate is located within the projection of the gate in the direction perpendicular to the substrate.

10. The array substrate according to claim 8, wherein the gate comprises a first gate and a second gate, the first gate is located between the substrate and the active layer, the second gate is located on a side of the active layer away from the substrate, and the projection of the active layer effective region in the direction perpendicular to the substrate at least partially overlaps at least one of projections of the first gate and the second gate in the direction perpendicular to the substrate.

11. The array substrate according to claim 10, wherein the active layer further comprises at least one third active portion, the first active portion, the second active portion and the third active portion are sequentially stacked in a direction away from the substrate; and
the first active portion and the second active portion jointly form a first active layer effective region, the second active portion and the third active portion jointly form a second active layer effective region, a projection of the first active layer effective region in the direction perpendicular to the substrate is located within a projection of the first gate in the direction perpendicular to the substrate, and a projection of the second active layer effective region in the direction perpendicular to the substrate is located within a projection of the second gate in the direction perpendicular to the substrate.

12. The array substrate according to claim 10, wherein the active layer further comprises at least one third active portion and at least one fourth active portion, and the first active portion, the second active portion, the third active portion and the fourth active portion are sequentially stacked in a direction away from the substrate; and
the first active portion and the second active portion jointly form a first active layer effective region, the third active portion and the fourth active portion jointly form a third active layer effective region, a projection of the first active layer effective region in the direction perpendicular to the substrate is located within a projection of the first gate in the direction perpendicular to the substrate, and a projection of the third active layer effective region in the direction perpendicular to the substrate is located within a projection of the second gate in the direction perpendicular to the substrate.

13. The array substrate according to claim 1, wherein an indium content of one of the first active portion and the second active portion close to the gate is lower than an indium content of another of the first active portion and the second active portion close to the gate.

14. The array substrate according to claim 1, wherein the active layer comprises a channel region and a doping region, the doping region is connected to the source-drain electrode, and a doping concentration in the doping region of one of the first active region and the second active region close to the gate is lower than a doping concentration in the doping region of another of the first active region and the second active region close to the gate.

15. The array substrate according to claim 1, wherein the thin film transistor comprises a first thin film transistor and a second thin film transistor, a size of the active layer of the first thin film transistor in a width direction is different from a size of the active layer of the second thin film transistor in the width direction, and the width direction intersects with the direction perpendicular to the substrate;
a number of the first active portion of the first thin film transistor is m11, and a number of the second active portion of the first thin film transistor is m12;
a number of the first active portion of the second thin film transistor is m21, and a number of the second active portion of the second thin film transistor is m22; and
m11+m12≠m21+m22.

16. The array substrate according to claim 1, wherein the array substrate comprises a first region and a second region surrounding at least a portion of the first region, the array substrate further comprises a driving circuit located at least in the first region and a control circuit located at least in the second region, the control circuit comprises the thin film transistor, and/or the driving circuit comprises the thin film transistor.

17. The array substrate according to claim 16, wherein the driving circuit comprises a first type transistor, a first power signal terminal and a second power signal terminal, the first type transistor is connected in series between the first power signal terminal and the second power signal terminal, and the first type transistor comprises the thin film transistor; and
the driving circuit further comprises a second type transistor, and a width-to-length ratio of the first type transistor is larger than a width-to-length ratio of the second type transistor.

18. The array substrate according to claim 16, wherein the control circuit comprises an output terminal and an output module, the output module comprises a first transistor and a second transistor, a first terminal of the first transistor is electrically connected to a clock signal terminal, a first terminal of the second transistor is electrically connected to a first level signal terminal, and a second terminal of the first transistor and a second terminal of the second transistor are electrically connected to the output terminal; and
at least one of the first transistor and the second transistor is the thin film transistor.

19. A display panel, comprising an array substrate, wherein the array substrate comprises:
a substrate; and
a thin film transistor, located on a side of the substrate, the thin film transistor comprising an active layer, a gate, and a source-drain electrode, the active layer comprising at least one first active portion and at least one second active portion, the first active portion and the second active portion being arranged in different layers, a projection of the first active portion in a direction perpendicular to the substrate and a projection of the second active portion in the direction perpendicular to the substrate being at least partially non-overlapping, the source-drain electrode being located on a side of the active layer away from the substrate, and the first active portion and the second active portion being connected to the source-drain electrode;
a non-overlapping region between the first active portion and the second active portion at least partially overlaps the gate in the direction perpendicular to the substrate; and
the first active portion and the second active portion comprise an oxide semiconductor.

20. A display device, comprising a display panel, wherein the display panel comprises an array substrate comprising:
a substrate; and
a thin film transistor, located on a side of the substrate, the thin film transistor comprising an active layer, a gate, and a source-drain electrode, the active layer comprising at least one first active portion and at least one second active portion, the first active portion and the second active portion being arranged in different layers, a projection of the first active portion in a direction perpendicular to the substrate and a projection of the second active portion in the direction perpendicular to the substrate being at least partially non-overlapping, the source-drain electrode being located on a side of the active layer away from the substrate, and the first active portion and the second active portion being connected to the source-drain electrode;
a non-overlapping region between the first active portion and the second active portion at least partially overlaps the gate in the direction perpendicular to the substrate; and
the first active portion and the second active portion comprise an oxide semiconductor.
